(19) United States
(12) Patent Application Publication
(10) Pub. No.: US 2006/0043597 A1
(43) Pub. Date: Mar. 2, 2006

(54) Solder composition, connecting process with soldering, and connection structure with soldering

(76) Inventors: Yoshiyuki Wada, Fukuoka-ken (JP); Tadahiko Sakai, Fukuoka-ken (JP); Seiichi Yoshinaga, Fukuoka-ken (JP)

Correspondence Address: WENDEROTH, LIND & PONACK L.L.P., 2033 K. STREET, NW, SUITE 800, WASHINGTON, DC, 20006, US

(21) Appl. No.: 11/209,620

(22) Filed: Aug. 24, 2005

(30) Foreign Application Priority Data
Aug. 25, 2004 (JP) 2004-245609

(51) Int. Cl. H01L 23/48

(52) U.S. Cl. 257/772

(57) ABSTRACT

There is provided a solder composition which contains: (1) a metal material comprising solder particles, and (2) a thermosetting flux material comprising a thermosetting resin and a solid resin which transforms to its liquid-like state when heated with a proviso that the thermosetting resin is excluded from the solid resin.

### TECHNICAL FIELD

The present invention relates to a solder composition, and particularly a solder composition in the form of a paste, that is, a solder paste which is used, for example, for solder-connecting an electronic part onto a substrate. In addition, the present invention relates to a connecting process as well as a connection structure with soldering with using such solder composition, and particularly such solder paste.

### BACKGROUND ART

A connecting process using soldering (that is, a connecting process with soldering) is widely used as a process for mounting an electronic part onto a substrate. Such electronic part is mounted with a fine pitch. Thus, when an amount of a solder material of a solder connection portion is small, or when a sufficient bonding strength of the solder connection portion is hardly ensured due to an insufficient strength of a solder material itself, a solder-connecting process is employed wherein the solder connection is reinforced by means of a reinforcing resin portion.

In order to form such reinforcing resin portion, a thermosetting resin such as an epoxy resin is often used, wherein a curing step is required so as to cure the thermosetting resin. When such curing is able to be carried out simultaneously in a reflow step wherein a solder connection portion is formed, it would be convenient since a connecting process with soldering becomes simpler. Therefore, in mounting the electronic part onto the substrate, a so-called “resin pre-application” may be employed wherein a connection material containing a thermosetting resin which is to form the resin reinforcing portion is applied to a portion where the electronic part is to be mounted before mounting the electronic part.

As a connection material which is used for the above “resin pre-application”, a thermosetting flux has been proposed which comprises a thermosetting resin, and also a solder paste has been proposed wherein solder particles (or solder powder) in contained in the thermosetting flux (see, for example, Patent Reference 1 indicated below). It is said that using such solder paste is advantageous in that the solder connection portion and also the reinforcing resin portion are both formed simultaneously between electrodes in a single step without supplying a solder material separately.
Patent Reference 1: Japanese Patent Kokai Publication No. 2001-219294

### DISCLOSURE OF THE INVENTION

The present inventors have found that even the connecting process with soldering, wherein the above solder paste which contains the solder particles in the thermosetting flux is used, does not readily provide a desired connection structure with soldering. Particularly, it is difficult to achieve a connection structure with soldering having a sufficient bonding strength. Thus, objects of the present invention are to provide a novel solder composition, and particularly such composition in the form of a paste which is able to provide a connection structure with soldering having a sufficient bonding strength, also to provide a connecting process with soldering wherein such solder composition is used, and further to provide a connection structure with soldering which is formed by using such solder composition.

After intensive studies by the present inventors as to the above objects, the following have been found:

When the solder paste wherein the solder particles are mixed in the known thermosetting flux as described above is used, it is difficult in a reflow step to fluidize (or move) molten solder particles as desired, which makes it difficult to form a connection structure with soldering having a sufficient bonding strength. In detail, the solder particles are melted by means of heating for the formation of the connection structure with soldering in the reflow step, but on the other hand, such heating have a curing reaction of the thermosetting resin proceed simultaneously. The thermosetting resin which is under such curing reaction prevents the movement (or flowing) of the molten solder particles, and as a result, it becomes difficult for the molten solder particles to contact with and to be integrated with other molten solder particles. Therefore, when being cooled thereafter, at least some of the molten solder particles are solidified while dispersed in the thermosetting resin which has already been cured, which makes it difficult to form an effectively continuous conductor portion made of a solder material, that is, a solder connection portion which contains a necessary amount of a solder material and also which has a sufficient bonding strength (i.e. an appropriate solder connection portion).

The present inventors have further intensively studied the formation of the appropriate solder connection portion by integrating the molten solder particles which move to gather together even when the curing reaction of the thermosetting resin is proceeding, and have concluded that coexistence of other material in the solder paste is effective which material is able to suppress the prevention of moving of the molten solder particles by the thermosetting resin which is under curing. Further additional studies thereafter have found that, as said other material, a solid resin, particularly a thermoplastic resin is suitable which is characterized in that it becomes in a liquid-like state when heated for the purpose of connecting with soldering with a proviso that such solid resin excludes a thermosetting resin, according to which the present invention has been completed.

Said other material as described above provides an effect in that said material suppresses the prevention of the movement of the molten solder particles regardless of the presence of the thermosetting resin which is under curing, and such effect may be likened to the provision of plasticity to the thermosetting resin which is under curing while it is losing its fluidity or flowability, and therefore in the sense of the above provision, said other material which provides with such effect may be said to be a kind of a plasticizer.

The present invention, therefore, provides a solder composition which comprises:
(1) a metal material comprising solder particles, and
(2) a thermosetting flux material comprising a thermosetting resin and a solid resin which changes (or transforms) to be in a liquid-like state when heated with a proviso that the thermosetting resin is excluded from the solid resin.

The solder composition according to the present invention is preferably in the form of a paste at normal temperature, and such preferable composition may be said to be a solder paste. Thus, the solder composition according to the present invention may optionally further comprise, in addition to the metal material and the thermosetting flux material, a component which is required to have the solder composition be in the paste form, for example a solvent (such as butyl carbitol, hexyl carbitol, methyl carbitol, and diethyl carbitol). The solder paste is advantageous in that its application to an object to be connected (such as an electrode) is easy, and another object to be connected (such as an electronic part) may be tentatively bonded to the applied solder paste using tackiness of the solder paste.

The solder composition such as a solder paste according to the present invention comprises the metal material and the thermosetting resin material. The metal material comprises at least the solder particles and it may further comprise other metal component. The thermosetting resin material comprises the thermosetting resin and the solid resin (excluding the thermosetting resin), and it may further comprise other component(s) as described below if necessary. The solid resin is in its solid state at normal temperature (which corresponds a temperature at which the solder composition is applied to the object, and usually in the range between 10° C. and 40° C.), and has a property that it becomes in its liquid-like state when it is heated so as to melt the solder particles.

The solder composition according to the present invention may be produced by mixing the metal material and the thermosetting flux material, and each material may be produced by mixing components which constitute each material. Such mixing may be carried out in any appropriate manner, and it is desirable as to the thermosetting flux material that the curing of the thermosetting resin does not start during mixing. It is noted that said other metal component or said other component as described above may be mixed to be contained by the metal material or the thermosetting flux material respectively, or said other metal component or said other component may be contained together by a mixture of the metal material and the thermosetting flux material upon mixing them to form such mixture. As said other component the following may be exemplified: a component which makes the solder composition to be in the paste form (e.g. a solvent), a curing accelerator, and said other metal component.

The solder particles used for the solder composition according to the present invention may be any appropriate particles as far as they form the solder composition according to the present invention as described in the present specification. For example, they may be particles of a metal, usually an alloy which is readily melted such as a so-called solder material, and a so-called lead-free solder material which does not contain a lead component. Concretely, the following solder materials may be exemplified: Sn—Ag—Cu, Sn—Ag, Sn—Cu, Sn—Bi, Sn—Zn, Sn—Ag—Bi—In, Sn—Ag—Cu—Bi and so on. It is noted that the size and the form of the solder particles are not particularly limited. For example, solder particles or solder powder which are commercially available, and particularly those which are commercially available for the electrically conductive adhesives or the solder pastes may be used as the solder particles for the solder composition according to the present invention.

The thermosetting resin used in the solder composition according to the present invention may be any appropriate one as far as it forms the solder composition according to the present invention as described in the present specification. Known thermosetting resins which are generally known to be used for the electrically conductive adhesives, the solder pastes or the like may be used. For example, the following resins may be exemplified: an epoxy resin, an acrylic resin, a urethane resin, a phenol resin, a urea resin, a melamine resin, an unsaturated polyester resin, an amine resin, a silicone resin and the like. The thermosetting resin used for the solder composition according to the present invention preferably comprises a main agent (or main ingredient) and a curing agent, and optionally, the thermosetting resin may further comprises a curing accelerator, and it is usually preferable that it comprises the curing accelerator.

The solid resin used in the solder composition according to the present invention may be any appropriate one as far as it forms the solder composition according to the present invention as described in the present specification, and it preferably comprises a thermoplastic resin. For example, the following resins may be exemplified: a terpene resin, a xylene resin, an amorphous rosin, an olefin resin, an acrylic resin, an amide resin, a polyester resin, a styrene resin, a polyimide resin, a fatty acid derivative wax, a highly polymerized rosin, a fatty acid amide and the like.

The above mentioned “(the solid resin) is characterized in that it becomes in a liquid-like state when heated” means that the solid resin in its solid state is changed (or transformed) to be in its liquid-like state through heating which melts the solder particles contained in the solder composition according to the present invention for the purpose of forming a connection structure with soldering. Such change may occur simultaneously with melting of the solder particles, and it is preferable that the change of the solid resin from its solid state to the liquid-like state is prior to the melting of the solder particles. It is noted that the present invention determines that the melting of the solder particles occurs when the solder particles are heated to a liquidus curve temperature of a solder material of which the solder particles are made (or a eutectic temperature in the case of a eutectic solder material).

As to the solder composition according to the present invention, it is preferable that the change of the solid resin from its solid state to its liquid-like state occurs prior to initiation of curing of the thermosetting resin, that is, the temperature at which the state of the solid resin changes to its liquid-like state is lower than the temperature at which the thermosetting resin starts to cure. However, the change may be substantially simultaneous with the initiation of curing, that is, there is no substantial difference between the temperature at which the state of the solid resin changes to its liquid-like state and the temperature at which the thermosetting resin starts to cure. In addition, as far as the appropriate connection portion, which is in turn an appropriate connection structure with soldering is ensured, the change may occur after the initiation of curing of the thermosetting resin, that is, the temperature at which the state of the solid resin changes to its liquid-like state is higher than the temperature at which the thermosetting resin starts to cure. In the present specification, the temperature at which the thermosetting resin starts to cure means a so-called cure initiation temperature. Such temperature is obtained by subjecting the thermosetting resin (including a curing agent and a curing accelerator if any) to the DSC measurement. Particulars as to the measurement can be seen from JIS K7121, which is incorporated by reference in their entity. Particularly, a temperature vs. calorie curve is obtained by the DSC measurement while a sample is heated, and the curing initiation temperature is defined as a temperature at which the curve starts to get away from a baseline of the curve. Such curing initiation temperature may be set variously by changing kinds of the main agent, the curing agent and the curing accelerator if any and/or a composition of them, and thus set curing initiation temperature may be determined by the method according to the above mentioned JIS.

In the present specification, the term “liquid-like” state is used to include not only the true liquid state but also a state which can be regarded as the liquid state. As far as the solder composition according to the present invention is constituted, a viscosity of the solid resin which is in the liquid-like state (i.e. the liquid state solid resin) may be high. Thus, the term “liquid-like” state is used so as to include a state which is very flowable like water, an organic solvent or the like as well as a state which is so viscous that it is generally not included within a concept of a usual liquid.

In a preferable embodiment, whether or not the solid resin is changed to be in the “liquid-like” state is determined by a softening temperature (or softening point) of the solid resin as a measure which is measured by the softening temperature testing method (a ring-and-ball method as defined in JIS K2207, which is incorporated by reference in their entity). That is, it has been found preferable to determine that, in the case wherein the solid resin heated, when the temperature of the solid resin is equal to or above the softening temperature of the solid resin, the solid resin is in the liquid-like state, and on the other hand, when the temperature of the heated solid resin is below the softening temperature of the solid resin, the solid resin is still in the solid state. In this embodiment, when the solid resin is heated, the softening temperature of the solid resin can be regarded to be a transition temperature from the solid state to the liquid-like state of the solid resin.

Thus, in a particularly preferable embodiment of the present invention, which of the melting of the solder particles and the change of the solid resin from the solid state to the liquid-like state occurs first is determined based on which of the liquidus curve temperature of the solder material forming the solder particles (or the eutectic temperature in the case of a eutectic solder material) and the softening temperature of the solid resin is lower. In one preferable embodiment according to the present invention, the liquidus curve temperature of the solder material of which the solder particles are made (or the eutectic temperature in the case of a eutectic solder material) is preferably equal to or higher the softening temperature of the solid resin, and the former temperature is higher than the latter temperature more preferably by at least 10° C., and particularly preferably by at least 20° C. In these preferable embodiments, the change of the solid resin to be in the liquid-like state occurs prior to the melting of the solder particles.

In the present invention, similarly to the above, which of the initiation of the curing of the thermosetting resin and the change of the solid resin from the solid state to the liquid-like state occurs first is preferably determined based on which of the curing initiation temperature of the thermosetting resin and the softening temperature of the solid resin is lower. As described above, it is preferable that the change of the solid resin from the solid state to the liquid-like state occurs earlier than the initiation of the curing of the thermosetting resin, so that the curing initiation temperature of the thermosetting resin is equal to or above the softening temperature of the solid resin. For example, the curing initiation temperature of the thermosetting resin is higher than the softening temperature of the solid resin preferably by at least 10° C., more preferably by at least 20° C., and particularly preferably by at least 30° C. It is noted that the curing initiation temperature is measured according to JIS K7121 as described above.

When the liquidus curve temperature of the solder material is equal to or above the softening temperature of the solid resin and/or the curing initiation temperature of the thermosetting resin is equal to or above the softening temperature of the solid resin as described above, an extent to which the flowability of the molten solder particles is prevented in the reflow step by means of the thermosetting resin contained in the solder composition which is under curing is lowered, so that good connection with soldering becomes possible.

It is noted that the solid resin is preferably compatible with thermosetting resin, particularly with the main agent thereof, wherein it is possible to form the solder paste having a sufficient flowability without using any volatile solvent when the solid resin is mixed into the thermosetting resin, particularly the main agent thereof. As a result, a problem(s) due to using the solvent such as deposition of its gas onto a reflow apparatus which gas is formed from the solvent, contamination of an apparatus atmosphere by means of such gas, and the like may be alleviated or deleted.

In the solder composition according to the present invention, it is preferable that the thermosetting flux material has an activity which removes an solder oxide film. In this embodiment, the thermosetting resin and/or the solid resin may have such activity. As the thermosetting resin having such activity, for example the expoxy resin, the acrylic resin, the phenol resin, and the amine resin may be exemplified. As the solid resin having such activity, for example the xylene resin and the amorphous rosin may be exemplified. In other embodiment, the thermosetting flux material may comprise a component having such activity (i.e. an activator) separately from the thermosetting resin and the solid resin. As such separate component, for example m-hydroxybenzoic acid, measaconic acid, o-hydroxycinnamic acid, usnic acid, 3,4-dihydroxybenzoic acid, hippuric acid, and succinic acid may be exemplified. Such activator may not be added to the thermosetting flux material, but may be added into the solder composition separately.

The solder composition according to the present invention contains, based on the total weight of the solder composition,

preferably 70 to 92% by weight, more preferably 75 to 90% by weight, and particularly 80 to 85% by weight of the metal material, and

preferably 8 to 30% by weight, more preferably 10 to 25% by weight, and particularly 15 to 20% by weight of the thermosetting flux material.

The thermosetting flux material contains, based on the total weight of the thermosetting flux material,

preferably 30 to 50% by weight, more preferably 35 to 50% by weight, and particularly 40 to 50% by weight of the main agent,

preferably 30 to 50% by weight, more preferably 35 to 50% by weight, and particularly 40 to 50% by weight of the curing agent, and

preferably 2 to 20% by weight, more preferably 2 to 15% by weight, and particularly 5 to 15% by weight of the solid resin.

In addition, the thermosetting flux material may further contain the curing accelerator, in which preferably 1 to 3% by weight, more preferably 1 to 2.5% by weight, and particularly 1 to 1.5% by weight of the curing accelerator is contained based on based on the total weight of the thermosetting flux material. Further, the thermosetting flux material may contain the solvent, in which not larger than 5% by weight, more preferably 0.5 to 3% by weight, and particularly 0.5 to 1% by weight of the curing accelerator is contained based on based on the total weight of the thermosetting flux material. Also, the thermosetting flux material may further contain the activator, in which preferably 3 to 10% by weight, more preferably 4 to 9% by weight, and particularly 5 to 7% by weight of the activator is contained based on the total weight of the thermosetting flux material.

The present invention also provides a connecting process with soldering wherein a first electrode such as a connection electrode of an electronic part (hereinafter, a term “connection electrode” is used generically for the purpose of simplicity) is connected with soldering to a second electrode such as a circuit electrode of a substrate (hereinafter, a term “circuit electrode” is used generically for the purpose of simplicity).

Such connecting process with soldering comprises the steps of:
locating the solder composition, preferably the solder paste according to the present invention as described above or below between the connection electrode and the circuit electrode;
heating to melt the solder particles (for example, by heating the substrate) wherein the solid resin is changed into its liquid-like state while the curing reaction of the thermosetting resin is made proceed; and
solidifying thus changed solid resin and the molten solder material (for example, by cooling the substrate, which may be done by returning the substrate temperature to normal temperature wherein the already cured thermosetting resin is also cooled).

When the solder particles are melted as described above, the molten solder particles gather together while moving to be integrated, so that they form a solder connection portion which electrically connects the connection electrode and the circuit electrode. Therefore, the present invention provides a process for producing the substrate onto which the electronic part is mounted wherein the electronic part is connected to the substrate with using the solder composition according to the present invention.

Further, the present invention provides a connection structure with soldering which electrically connects the first electrode and the second electrode (for example, the connection electrode and the circuit electrode, respectively), which structure is formed by the above described connecting process with soldering. Such connection structure with soldering is formed by locating the solder composition, preferably the solder paste according to the present invention as described above or below between the first electrode and the second electrode; changing the solid resin into its liquid-like state while the curing reaction of the thermosetting resin is made proceed upon melting the solder particles (for example, by heating the substrate); and then solidifying the solid resin in the liquid-like state and the molten solder material (for example, by cooling the substrate). The connection structure with soldering comprises a solder connection portion which is formed between the first electrode and the second electrode and a reinforcing resin portion made of the cured thermosetting resin and the solidified solid resin wherein the reinforcing resin portion covers at least a portion of a surface of the solder connection portion.

### EFFECT OF THE INVENTION

According to the solder composition or the connecting process with soldering according to the present invention, the flowability of the solder particles which have been melted in the reflow step is more sufficiently ensured when compared with using the conventional solder paste, so that the solder connection portion which is in a more appropriate form and which has a sufficient bonding strength. As a result, the connection structure with soldering which is formed by such solder composition and such connecting process with soldering has the appropriate solder connection portion.

### BRIEF DESCRIPTION OF DRAWINGS

FIG. 1 shows steps of a process of mounting an electronic part onto a substrate which process is one embodiment of the connecting process with soldering according to the present invention.

FIG. 2 shows a cross-sectional view of a connection structure with soldering of one embodiment according to the present invention.

FIG. 3 shows a cross-sectional view of a connection structure with soldering of one embodiment according to the present invention.

FIG. 4 shows examples of a defect which is caused when using the conventional solder paste.

In the drawings, numerals indicate the following elements:
1 . . . substrate, 2 . . . electrode, 3 . . . solder paste,
4 . . . electronic part,
5 . . . connection structure with soldering,
5a . . . solder connection portion,
5b . . . reinforcing resin portion

### EMBODIMENTS FOR CARRYING OUT THE INVENTION

In the solder composition according to the present invention, an amount of the metal material is preferably 70 to 92% by weight based on the total weight of the solder composition, and the balance may be the thermosetting flux material. Substantially all of the metal material may be the solder particles, and in other embodiment, a portion of the metal material may be other metal component, particularly powder of said other metal component as described below.

Upon carrying out a connection process with soldering while using the solder composition according to the present invention, when heating to a rather higher temperature is allowable, for example particles of a solder material based on Sn (tin)-Ag (silver)-Cu (copper) (of which liquidus curve temperature is about 220° C.) may be used for the solder composition according to the present invention. On the other hand, when the heating temperature is required to be as low as possible, for example, particles of a solder material based on Sn (tin)-Bi (bismuth) (of which liquidus curve temperature is about 139° C.) may be used for the solder composition according to the present invention.

It is noted that the metal material may include, in addition to the solder particles, metal powder of for example Ag (silver), Pd (palladium) and/or Au (gold). Such metal powder may preferably be in the form of flakes or particles, and the metal powder may be particularly in the form of fine foil elements (or fine flake elements). Such metal powder may be contained in an amount of 0.5 to 10% by weight, and preferably 0.5 to 5% by weight based on the total weight of the metal material of the solder composition so that connecting with soldering is improved. The above mentioned metals for such metal powder have a melting point which is higher than the used solder material, are unlikely to form an oxide film in the atmosphere, and help the molten solder material in its flowable state flow over the metal powder, so that the metal powder provides nuclei around which molten solder particles gather, whereby the wetting property of the solder material is improved. When using the Sn—Bi solder material, 1 to 3% by weight of Ag (silver) (which is preferably in the form of particles) may be included by the metal material based on the total weight of the metal material, and such inclusion of silver is able to improve the bonding strength of the solder connection portion.

The thermosetting resin which forms the solder composition according to the present invention may be any appropriate one as described above. Thus, those skilled in the art are able to select an appropriate thermosetting resin based on the disclosure of the present specification, and no additional explanation is required. In one example wherein an epoxy resin is used as the main agent, the following main agent, curing agent and curing accelerator may be used to obtain a thermosetting flux material. It is noted that the unit “% by weight” is based on the total weight of the thermosetting flux material.
Main Agent (for example 30 to 40% by weight):
   hydrogenated bisphenol A epoxy resin
   (3,4-epoxycyclohexyl)methyl 3′,4′-epoxycyclohexyl-carboxylate (commercially available as CELLOXIDE 2021P from Daicel Chemical Industries, Ltd.)
   bisphenol F epoxy resin
   bisphenol A epoxy resin
Curing Agent (for example 30 to 40% by weight):
   methyl cyclohexene-dicarboxylic anhydride (tetrahydromethylphthalic anhydride)
   methylhexahydrophthalic anhydride
Curing Accelerator (for example 1 to 2% by weight):
   2-phenyl-4-methyl-5-hyroxymethyl imidazole
   2-phenyl-4,5-dihyroxymethyl imidazole

In addition to the above three components, the thermosetting resin or the thermosetting flux material may contain the activator (for example 3 to 10% by weight), the solvent (for example up to 5% by weight) or the like.

Thus, those skilled in the art are able to prepare an appropriate thermosetting flux material which forms the solder composition according to the present invention based on the disclosure of the present specification, and no additional explanation is required. In one example wherein the epoxy resin is used, the following formulation may be used for the thermosetting flux material. It is noted that the unit “% by weight” is based on the total weight of the thermosetting flux material.
Main Agent (for example 30 to 40% by weight):
   hydrogenated bisphenol A epoxy resin
Curing Agent (for example 30 to 40% by weight):
   tetrahydromethylphthalic anhydride
Curing Accelerator (for example 1 to 2% by weight):
   2-phenyl-4-methyl-5-hyroxymethyl imidazole
Activator (for example 3 to 10% by weight):
   m-hydroxybenzoic acid
Solvent (for example up to 5% by weight)
   butyl carbitol
Solid Resin (for example 3 to 20% by weight):
   alkylphenol modified xylene resin

The above thermosetting resin has a curing initiation temperature above 70° C. when blended according to the above formulation. Therefore, when an alkylphenol modified xylene resin having a softening temperature of 70° C. is used as the solid resin, the softening temperature of the solid resin is lower than the curing initiation temperature.

The following are to be noted:

In place of the hydrogenated bisphenol A epoxy resin, (3,4-epoxycyclohexyl)methyl 3′,4′-epoxycyclohexyl-carboxylate, a bisphenol F epoxy resin or a bisphenol A epoxy resin may be used as the main agent.

In place of tetrahydromethylphthalic anhydride, methylhexahydrophthalic anhydride may be used as the curing agent.

In place of 2-phenyl-4-methyl-5-hyroxymethyl imidazole, 2-phenyl-4,5-dihyroxymethyl imidazole may be used as the curing agent.

In place of m-hydroxybenzoic acid, measaconic acid may be used as the activator.

In place of the alkylphenol modified xylene resin, a fatty acid amide or a highly polymerized rosin may be used as the solid resin.

In place of butyl carbitol, methyl carbitol may be used as the solvent.

Amounts of the above alternatively usable components may be the same as those of the components to be replaced. When an acid anhydride is used as the curing agent, the addition of the activator may be omitted since the acid anhydride has an activity to remove a solder oxide film.

When the solder composition according to the present invention contains the particles of a lead-free solder material, the following formulations are recommendable as one examples of the thermosetting flux material:

In the case wherein the Sn—Ag—Cu solder material (liquidus curve temperature: 220° C.) is used,
Weight Ratio of metal material (whole of which may be the solder particles) to thermosetting flux material=8:1
Main Agent: hydrogenated bisphenol A epoxy resin (38% by weight)
Curing Agent: tetrahydromethylphthalic anhydride (38% by weight)
Curing Accelerator: 2-phenyl-4-methyl-5-hyroxymethyl imidazole (1% by weight)
Activator: m-hydroxybenzoic acid (10% by weight)
Solid Resin: highly polymerized rosin (softening temperature: 140° C.) (13% by weight)
Note: The unit “% by weight” is based on the total weight of the thermosetting flux material.

In the case wherein the Sn—Bi solder material (liquidus curve temperature: 139° C.) is used,
Weight Ratio of metal material (whole of which may be the solder particles) to thermosetting flux material=8:1
Main Agent: hydrogenated bisphenol A epoxy resin (38% by weight)
Curing Agent: tetrahydromethylphthalic anhydride (38% by weight)
Curing Accelerator: 2-phenyl-4-methyl-5-hyroxymethyl imidazole (1% by weight)
Activator: m-hydroxybenzoic acid (10% by weight)
Solid Resin: alkylphenol modified xylene resin (softening temperature: 120° C.) (13% by weight)
Note: The unit “% by weight” is based on the total weight of the thermosetting flux material.

Next, the present invention will be explained with reference to the drawings by means of one example wherein an electronic part is connected to a circuit substrate, and particularly the electronic part is mounted onto the circuit substrate by connecting a connection electrode of the electronic part to a circuit electrode of the substrate.

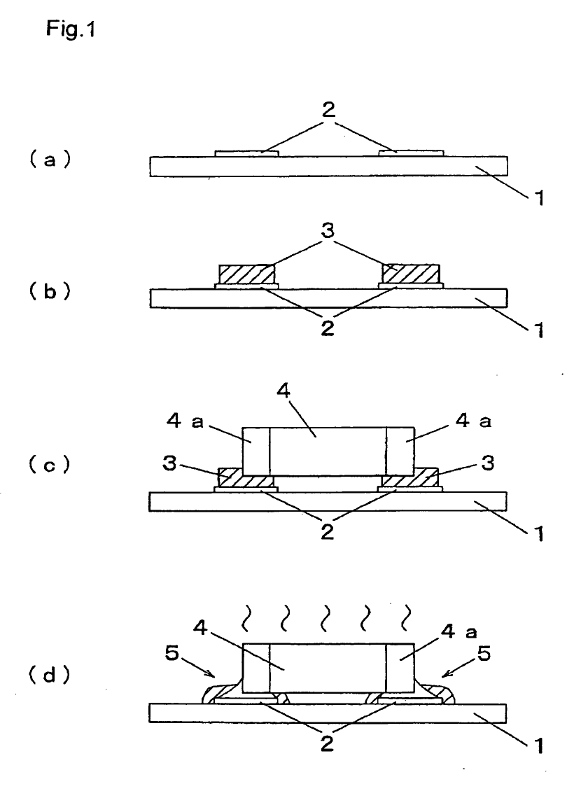

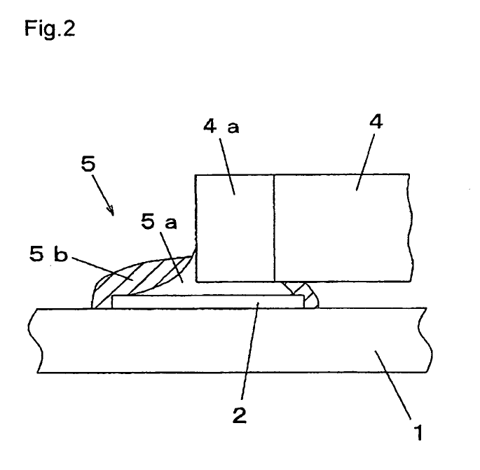

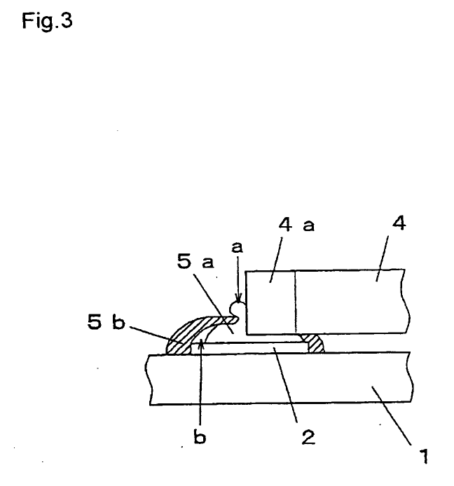

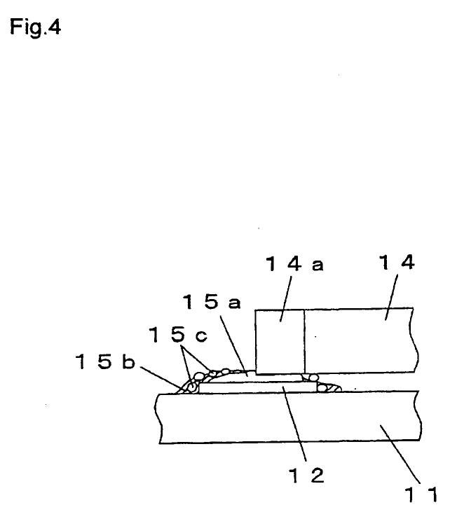

FIG. 1 schematically shows the steps of a process of mounting an electronic part by means of the connecting process with soldering according to the present invention when viewing from a side of the electronic part. It is noted that in FIG. 1(d), only a connection structure with soldering is shown in its cross-sectional view. FIG. 2 schematically shows, in a cross-sectional view, a connection structure with soldering as one embodiment according to the present invention. FIG. 3 schematically shows, in a cross-sectional view, a connection structure with soldering as one embodiment according to the present invention which has been heated again. FIG. 4 schematically shows examples of a defect which is caused through a connecting process with soldering wherein the conventional solder paste is used.

First, with referring to FIG. 1, the process of mounting the electronic part is explained which process is one embodiment of the connecting process with soldering according to the present invention. The mounting process uses the solder composition according to the present invention as described above and below is used as a solder paste, and mounts the electronic part onto the substrate by solder-connecting the connection electrode of the electronic part to the circuit electrode which is formed on the substrate.

Referring to FIG. 1(a), the circuit electrode 2 (hereinafter, referred to as merely “electrode 2”) is formed on the substrate 1. The connection electrodes 4 of the electronic part 4 which is to be mounted onto the substrate 1 are solder-connected to the electrodes 2 respectively. Prior to placing the electronic part 4 on the substrate, the solder paste 3 is applied to surfaces of the electrodes 2 as shown in FIG. 1(b). For the application of the solder paste 3, any known appropriate application manner such as screen printing, application with using a dispenser or the like may be used.

Then, the electronic part 4 in the form of a chip is placed on the substrate 1. That is, terminals 4a as the connection electrodes which are present at the both ends of the electronic part 4 are aligned with the electrodes 2, and the terminals 4a are placed down on the solder paste 3 on the electrodes 2 as shown in FIG. 1(c). By such placing down, the electronic part 4 is tentatively bonded due to the tackiness of the solder paste 3. Thereafter, the substrate 1 onto which the electronic part 4 has been mounted is passed to a reflow apparatus, in which the substrate is heated to a temperature which is equal to or above the liquidus curve temperature of the solder material forming the solder particles in the solder paste 3. By means of such heating, the solder particles in the solder paste 3 are melted and moved so as to gather together and thereby a solder connection portion is formed as shown in FIG. 1(d) while advancing the curing of the thermosetting resin in the solder paste 3. During such heating, the solid resin is changed to its liquid-like state concurrently so that a reinforcing resin portion is formed with the thermosetting resin which has been cured.

Thereafter, the substrate 1 is removed out from the reflow apparatus so as to return it to be in normal temperature, and thereby the solid resin which has been changed into its liquid-like state and the molten solder material which has been made from the solder particles are cooled to be solidified. In this way, the solder connection portion 5a is formed in the form of an appropriate fillet which connects the electrode 2 and the terminal 4a (see FIG. 2). Thus, using the solder paste 3, the connection structure with soldering 5 is formed wherein the terminal 4a as the connection electrode of the electronic part 4 and the electrode 2 of the substrate 1 are connected with soldering.

Since the solid resin of the thermosetting flux material contained in the solder composition 3 changes to its liquid-like state when the solder particles are melted as described above, the thermosetting flux material prevents the flowability of the molten solder particles not so severely even though it is heated to such a temperature that the solder particles are melted. As a result, the prevention of the self-alignment effect of the molten solder material is suppressed, so that an appropriate solder connection portion is formed. After the completion of such connecting with soldering, by means of the completion of curing of the thermosetting resin and the solidification of the solid resin by being cooled to normal temperature which resin has once been in the liquid-like state in the thermosetting flux material, the cured thermosetting resin and thus solidified solid resin become in a sufficiently rigid state, which functions as the reinforcing resin portion 5b which covers at least a portion of a surface of the solder connection portion 5a and reinforces the solder connection portion 5a.

Such connection structure with soldering 5 is formed by placing the solder paste 3 between the electrode 2 and the terminal 4a followed by heating the substrate 1 so as to melt the solder particles, and then cooling the substrate. The structure includes as shown in FIG. 2 the solder connection portion 5a which is formed between the electrode 2 and the terminal 4a, and the reinforcing resin portion 5b which is formed of the thermosetting resin cured by being heated and the solid resin solidified by being cooled. The reinforcing resin portion 5b covers at least a portion of, preferably most of, and more preferably substantially all of the surface of the solder connection portion.

The connecting process with soldering as described above comprises the step of placing the solder paste 3 having the above described composition between the electrode 2 and the terminal 4a, the step of heating the substrate 1 so as to melt the solder particles wherein the curing reaction of the thermosetting resin is made proceed while the solid resin is changed into its liquid-like state, and the step of solidifying thus changed solid resin and the molten solder material by cooling the substrate 1 to normal temperature. In the above heating step, it is particularly preferable that the change of the solid resin into its liquid-like state occurs prior to the melting of the solder particles and/or the curing initiation of the thermosetting resin. In this particularly preferable case, it is more preferable that the melting of the solder particles precedes the curing initiation of the thermosetting resin. That is, it is most preferable that the change of the solid resin into its liquid-like state occurs first, the melting of the solder particles occurs second, and the curing initiation of the thermosetting resin occurs last. In other embodiment, these three matters occur substantially concurrently.

It is noted that the present invention, in its broadest sense, resides in that the presence of the solid resin in the solder composition provides the appropriate solder connection portion covered with the reinforcing resin portion in the connection structure with soldering. Therefore, as far as such connection structure with soldering is provided, the above three matters occurs in any possible order.

Using the above described connecting process with soldering according to the present invention suppresses the occurrence of the insufficient connection which is likely to be formed when using the conventional solder paste for mounting a similar electronic part 14. For example, FIG. 4 schematically shows, in a cross-sectional view, a connection structure with soldering formed when a terminal 14a of the electronic part 14 is connected to an electrode 12 by using a solder paste which contains solder particles of Sn—Bi lead-free solder materials while no solid resin as described above is contained therein.

As to such connection structure with soldering, it is difficult to form a solder connection portion having an appropriate fillet form, so that a sufficient bonding strength is often not ensured. That is, at least a portion and usually not a little portion of the solder particles is likely to remains dispersed as solder particles 15c in the form of balls or other forms in the cured thermosetting resin 15b in the reflow step, so that thus formed solder connection portion 15a tends to include an insufficient amount of the solder material and also to be in an irregular form.

Contrary to the above, using the solder composition which contains the solid resin in the thermosetting flux material according to the present invention provides the following effects: Heating upon the reflow generally results in the degradation of the flowability of the thermosetting flux material due to the curing of the thermosetting resin. However, before, after or simultaneously with such degradation, the change of the solid resin into its liquid-like state occurs, and such change is able to at least partly compensate for the degradation. Thereby, possibility that the gathering of the molten solder particles is prevented by the thermosetting resin which is under curing gets smaller, so that the gathering of the molten solder particles becomes more possible, which results in the formation of the solder connection portion having a more appropriate form.

Further, after the reflow step, the solder connection portion is covered by the reinforcing resin portion which is formed by solidifying the changed solid resin through cooling which solid resin remains compatibilized with the cured thermosetting resin, so that a brittle solder connection portion having a less bonding strength is reinforced which portion is formed by using a lead-free solder material having a lower melting point, whereby connection reliability of the solder connection portion is able to be ensured.

FIG. 3 schematically shows a possible state of a connection structure with soldering which is formed by using the solder composition which contains the solid resin according to the present invention wherein the liquidus curve temperature of the solder material is lower than the temperature at which the solid resin changes into its liquid-like state, for example its softening temperature. For example, in a production process of a mounted substrate wherein a number of electronic parts are mounted onto both sides of the substrate, some electronic parts which have once been mounted onto a first side of the substrate is again heated in another reflow step when the other electronic parts are connected with soldering onto a second side of the substrate.

In such case, the solder connection portion 5a which has once been solidified is again heated above its liquidus curve temperature so that it melts and becomes in the flowable state. Simultaneously, the reinforcing resin portion 5b which covers the solder connection portion 5a is heated similarly. If the softening temperature of the solid resin is higher than the liquidus curve temperature, the solid resin remains in the solid state when the solder material melts, so that the reinforcing resin portion 5b as a whole is substantially not in a soft state but in the solid state. Such reinforcing resin portion 5b prevents free expansion of the solder material which is formed of the molten state of the solder connection portion 5a. As a result, the molten solder material may get out through a gap between the reinforcing resin portion 5b and the terminal 4a (see the arrow “a” in FIG. 3) or there may be formed a void in the reinforcing resin portion due to flowing out of the solder material (see the arrow “b” in FIG. 3), which may induce an irregular form of the solder connection portion 5a.

Contrary to the above, when the combination of the solder material for the solder particles and the thermosetting flux material is so selected according to the present invention that the liquidus curve temperature of the solder material is higher than the temperature at which the solid resin changes to its liquid-like state, for example the softening temperature of the solid resin, the solid resin has already been in its liquid-like state upon the melting of the solder material, which ensures that the reinforcing resin portion is already in its soft state before the melting of the solder material, so that it does not interfere the free expansion of the molten solder material. As a result, the occurrence of the defects may be prevented which are caused by interfering the free expansion of the molten solder material.

As described above, according to the connecting process with soldering of the present invention, the solder composition comprising the metal material which contains the solder particles and the thermosetting flux material which contains the solid resin as described above is used in the connecting process which employs the so-called “resin pre-application”. Thereby, the flowability of the molten solder particles or molten solder material is ensured in the reflow step, which results in the formation of a solder connection portion having an appropriate form (for example, in a desired fillet form) and a sufficient bonding strength.

### EXAMPLES

Production of Solder Paste

Various solder compositions as the solder pastes were prepared by mixing components in various formulations as shown in Table 1 below. It is noted that each component of the formulations is indicated in a unit of “parts by weight” in Table 1.

First, the solid resin and the epoxy resin as the main agent were heated and mixed at a temperature above the softening temperature of the solid resin.

To thus resulted mixture, the acid anhydride as the curing agent, the curing accelerator, the activator and the solvent were blended and kneaded together at a room temperature to obtain the thermosetting flux material. A planetary mixer or rolls were used for such kneading.

The 42Sn-58Bi solder particles (commercially available from Mitsui Kinzoku, trade name: solder powder, average diameter: 0.03 mm, melting point: 139° C.) were blended with thus obtained thermosetting flux material at a room temperature with a planetary mixer to obtain the solder paste. A weight ratio of the solder particles to the thermosetting flux material was 83:17.

TABLE 1

| | com- | softening | Example | Example | Example |
|---|---|---|---|---|---|
| component | pound | temperature | 1 | 2 | 3 |
| main agent | a) | | 40 | 40 | 40 |
| curing | b) | | 40 | 40 | 40 |
| agent | | | | | |
| curing | c) | | 1.5 | 1.5 | 1.5 |
| accelerator | | | | | |
| activator | d) | | 7 | 7 | 7 |
| solid | e1) | 70° C. | 11.5 | | |
| resin | e2) | 120° C. | | 11.5 | |
| | e3) | 150° C. | | | 11.5 |
| solvent | f) | | 0.5 | 0.5 | 0.5 |
| total | | | 100.5 | 100.5 | 100.5 |
| number of | | | not more | not more | not more |
| solder balls | | | than 2 | than 2 | than 2 |
| | | | ∘ | ∘ | ∘ |
| solder | | | not | not | deformed |
| deformation | | | deformed | deformed | ∘ |
| test | | | ∘ | ∘ | |
| bonding | | | ∘ | ∘ | ∘ |
| strength | | | | | |
| test | | | | | |

a) hydrogenated bisphenol A epoxy resin
b) tetrahydromethylphthalic anhydride
c) 2-phenyl-4-methyl-5-hyroxymethyl imidazole
d) m-hydroxybenzoic acid
e1) alkylphenol modified xylene resin (commercially available from Fudow Co., Ltd., trade name: Nikanol HP-70)
e2) alkylphenol modified xylene resin (commercially available from Fudow Co., Ltd., trade name: Nikanol HP-120)
e3) alkylphenol modified xylene resin (commercially available from Fudow Co., Ltd., trade name: Nikanol HP-150)
f) butyl carbitol
◯: success in test, X: rejection in test
   Connecting with Solder Paste

Using a metal mask having a thickness of 100 μm and openings (size: 0.4 mm×0.5 mm), thus obtained solder paste was applied on electrodes formed on a substrate (FR4 substrate having a thickness of 0.6 mm) with a printer. Electronic parts (1005 chip) were placed on the printed solder paste layers on the electrodes with a chip mounter.

Then, the substrate was heated on a hot plate heated to 200° C. for three minutes so as to melt the solder particles, followed by cooling the substrate to a room temperature, so that the electronic parts were mounted onto the substrate.

Estimation of Connection Structure with Soldering

(Bonding Strength Test of Connection Structure)

Using a tool having a wedge form edge, a force was applied to the electronic part so as to separate the part, and a shear force when the part was separated (a so-called shear strength) was measured. The tool had an edge angle of 60°, and it was moved at a speed of 100 mm/min. For the measurement, a tensile testing machine (commercially available from Aiko Engineering Co., Ltd., trade name: 1605HTP) equipped with a load cell of 50 N was used.

As a Comparative Example, using a solder paste (commercially available from Tamura Corporation, trade name: LFSOLDER401-11, including Sn—Bi eutectic solder material) in place of the solder paste according to the present invention, the electronic parts were similarly mounted and the shear strength was similarly measured.

The shear strength of the Comparative Example was 29 N. Based on such strength, it was determined that when the connection structure with soldering has a shear strength which is as at least 1.5 times as that of the Comparative Example, such structure passes this bonding strength test.

The shear strengths of the connection structures with soldering formed by using the solder compositions according to the present invention were measured, and all of the structures passed the bonding strength test as shown in above Table 1. That is, the shear strength was not smaller than 44 N in each of the Examples. Thus, it has been found that the connection structure with soldering obtained by using the solder paste according to the present invention has a sufficient bonding strength.

(Solder Ball Number Test)

Using a microscope, the balls of the formed connection structure with soldering around the electronic part connected as described above were counted. It was determined that when the number is not larger than two, the connection structure passes the solder ball number test. The results are shown in above Table 1.

(Solder Deformation Test Through Re-Reflow)

The substrate onto which the electronic part was already mounted was again placed on the hot plate which was heated to 200° C. for three minutes, and the solder material was again melted. This test simulates that the already formed solder connection portion of the connection structure is again melted, that is, re-reflowed. Thereafter, the substrate was cooled to a room temperature, and observed as to whether or not the form of the solder connection portion is deformed after the above heating while comparing with the form of the solder connection portion before the above heating using microphotographs. When deformation was observed, the connection structure with soldering was determined to be rejected. The results are shown in above Table 1.

### INDUSTRIAL APPLICABILITY OF THE INVENTION

The solder composition and the connecting process with soldering according to the present invention provide the solder connection portion having the appropriate form and the sufficient bonding strength, and therefore, they and also the connection structure with soldering according to the present invention can be used for the applications wherein an electronic part is mounted onto a substrate with soldering.

Particularly, by using, in the present invention, a lead-free solder material having a lower melting point, especially an Sn—Bi solder material as the solder material for the solder particles, the following advantages may be provided.

Recently, according to the requests as to the environmental protection, the lead-free solder material has mainly been used in the electronic industrial fields. An Sn—Ag—Cu solder material which is generally used has a liquidus curve temperature of 220° C., which is rather higher when compared with that of the conventional Sn—Pb eutectic solder material. Therefore, it is difficult to apply such lead-free solder material to a substrate or an electronic part of which allowable temperature limit is low.

To the contrary, an Sn—Bi solder material has a liquidus curve temperature of 139° C., and thus it is expected that such solder material is applicable to an electronic part of which allowable temperature limit is low (such as a CCD, an aluminum electrolytic capacitor or the like). On the other hand, the Sn—Bi solder material is relatively mechanically brittle, and also it is difficult for such solder material to form a solder connection portion having an appropriate form through the reflow step when using with the conventional solder paste as described above, so that the connection reliability is not sufficient and therefore the field to which the Sn—Bi solder material is applicable has been limited.

When such Sn—Bi solder material having the above mentioned features is used in the form of the solder paste in which the thermosetting flux material including the solid resin is mixed according to the present invention, the field to which the Sn—Bi solder material is applicable is greatly broadened. With the solder composition, for example the solder paste according to the present invention, the reduction of the flowability of the thermosetting flux material due to the curing of the thermosetting resin in the reflow step can be compensated by the solid resin which has been changed to its liquid-like state and functions as a plasticizer.

Therefore, an extent to which the gathering of the molten solder particles is prevented by the thermosetting flux material is lowered, so that the solder connection portion having a more appropriate form is able to be provided. In addition, the formed solder connection portion is covered and reinforced by the reinforcing resin portion which is made of the cured thermosetting resin and the solidified solid resin, which compensates the insufficient bonding strength of the Sn—Bi solder material, so that the connection reliability is improved.

The present invention thus provides a connecting process in which the Sn—Bi solder material as a low melting point solder material is industrially applied, so that such process expands its applicable field to the substrates, the electronic parts and the like of which allowable temperature is low as described above. Simultaneously, an additional advantage is expected in that the heating temperature of the reflow step can be set at a lower temperature so that for example the number of preheating stages may be reduced, the reflow apparatus may be more compact, and/or the electric power consumption may be decreased.

Further, there is no need of a costly conventional connecting process in which connecting with soldering at a low temperature is required due to the allowable temperature upper limit of heating, such as a process wherein an Ag paste is used which contains silver powder in a resin adhesive, or a soldering process in which locally heating by means of laser beam or Softbeam so as to connect individually without heating a whole substrate, so that neither costly material nor apparatus is required, which results in the cost reduction upon connecting with soldering.

In addition, since the liquidus curve temperature of the low melting point lead-free solder material is considerably lower than that of the Sn—Pb eutectic solder material (189° C.), it is possible to use a material having a low allowable temperature which has been considered to be unusable (for example a less expensive material such as a paper-phenol resin material), and there is no need of a costly material such as a BT (bismaleimide-triazine) resin, which results the reduction of the material cost.

What is claimed is:

1. A solder composition which comprises:
(1) a metal material comprising solder particles, and
(2) a thermosetting flux material comprising a thermosetting resin and a solid resin which transforms to its liquid-like state when heated with a proviso that the thermosetting resin is excluded from the solid resin.

2. The solder composition according to claim 1 wherein a liquidus curve temperature of a solder material of the solder particles is not lower than a softening temperature of the solid resin.

3. The solder composition according to claim 2 wherein the liquidus curve temperature of a solder material of the solder particles is higher than the softening temperature of the solid resin by at least 10° C.

4. The solder composition according to claim 1 wherein the thermosetting flux material has an activity to remove an oxide film of the solder particles.

5. The solder composition according to claim 1 wherein a solder material which forms the solder particles contains tin and bismuth.

6. The solder composition according to claim 1 wherein it is in the form of a paste.

7. The solder composition according to claim 1 wherein the thermosetting resin comprises:
at least one as a main agent selected from the group consisting of an epoxy resin, an acrylic resin, a urethane resin, a phenol resin, a urea resin, a melamine resin, an unsaturated polyester resin, an amine resin and a silicone resin; and
at least one curing agent which cures the main agent.

8. The solder composition according to claim 1 wherein the solid resin comprises at least one selected from the group consisting of a terpene resin, a xylene resin, an amorphous rosin, an olefin resin, an acrylic resin, an amide resin, a polyester resin, a styrene resin, a polyimide resin, a fatty acid derivative wax, a highly polymerized rosin and a fatty acid amide.

9. The solder composition according to claim 7 wherein the solid resin is compatible with the main agent.

10. A connecting process with soldering in which an electrode as a first electrode is connected to other electrode as a second electrode, comprising the steps of:
locating the solder composition according to claim 1 between the first electrode and the second electrode;
heating these electrodes and the solder composition so as to melt the solder particles wherein the solid resin is changed into its liquid-like state while a curing reaction of the thermosetting resin is made proceed; and
solidifying said solid resin and molten solder material.

11. The connecting process according to claim 10 wherein the first electrode is a connection electrode of an electronic part, and the second electrode is a circuit electrode formed on a substrate.

12. A production process of a substrate which has an electronic part thereon, comprising the step of connecting the electronic part to the substrate using the connecting process with soldering according to claim 11

13. A connection structure with soldering between an electrode and other electrode which structure is formed by using the connecting process with soldering according to claim 10, comprising
a solder connection portion connecting those electrodes, and
a reinforcing resin portion which is made of the solidified solid resin and the cured thermosetting resin.

14. The connection structure with soldering according to claim 13 wherein the reinforcing resin portion covers at least partly a surface of the solder connection portion.
